(19) United States
(12) Patent Application Publication
(10) Pub. No.: US 2026/0142466 A1
(43) Pub. Date: May 21, 2026

(54) RADIO FREQUENCY CIRCUIT, RADIO FREQUENCY POWER-SUPPLY DEVICE, AND REACTANCE COMPENSATION METHOD

(71) Applicant: SHENZHEN RSPOWER TECHNOLOGY CO., LTD., Shenzhen (CN)

(72) Inventors: Shuxiao WANG, Shenzhen (CN); Yati CHEN, Shenzhen (CN)

(21) Appl. No.: 19/449,963

(22) Filed: Jan. 15, 2026

Related U.S. Application Data
(63) Continuation of application No. PCT/CN2024/115696, filed on Aug. 30, 2024.

(30) Foreign Application Priority Data
Dec. 18, 2023 (CN) 202311734436.9

(51) Int. Cl. H02J 3/1807; H03H 7/38

(52) U.S. Cl. CPC H02J 3/1807; H03H 7/38

(57) ABSTRACT

A radio frequency (RF) circuit, an RF power-supply device, and a reactance compensation method are provided. The RF circuit includes an RF power supply, an RF output end, a transformer, a reactance compensation unit, and a transformation-ratio adjustment unit. The RF power supply is configured to provide RF power to a load. The transformer includes a primary winding and a secondary winding. The primary winding is connected between the RF power supply and the RF output end. The reactance compensation unit is connected in series with the secondary winding of the transformer, and is configured to selectively provide a compensatory reactance. When reactance compensation is required for the RF circuit, the reactance compensation unit is configured to provide the compensatory reactance and the transformation-ratio adjustment unit is configured to adjust the transformation ratio of the transformer, to compensate a reactance at a primary winding side of the RF circuit.

### CROSS-REFERENCE TO RELATED APPLICATION(S)

This application is a continuation of International Application No. PCT/CN 2024/115696, filed Aug. 30, 2024, which claims priority to Chinese Patent Application No. 202311734436.9, filed Dec. 18, 2023, the entire disclosure of which are hereby incorporated by reference.

### TECHNICAL FIELD

The disclosure relates to the field of radio frequency (RF) technology, and in particular, to an RF circuit, an RF power-supply device, and a reactance compensation method.

### BACKGROUND

At present, with the popularization of various radio frequency (RF) applications, it becomes more and more important to perform impedance matching on an RF circuit, so as to obtain a maximum power value of a load.

### SUMMARY

In a first aspect, a radio frequency (RF) circuit is provided. The RF circuit includes an RF power supply, an RF output end, a transformer, a reactance compensation unit, and a transformation-ratio adjustment unit. The RF power supply is configured to provide RF power to a load. The RF output end is configured to be connected to the load. The transformer includes a primary winding and a secondary winding. The primary winding is connected between the RF power supply and the RF output end. The reactance compensation unit is connected in series with the secondary winding of the transformer, and is configured to selectively provide compensatory reactance. The transformation-ratio adjustment unit is configured to adjust a transformation ratio of the transformer. When reactance compensation is required for the RF circuit, the reactance compensation unit is configured to provide the compensatory reactance, and the transformation-ratio adjustment unit is configured to adjust the transformation ratio of the transformer, to compensate a reactance at a primary winding side of the RF circuit.

In a second aspect, an RF power-supply device is further provided. The RF power-supply device includes the aforementioned RF circuit and further includes a detection unit and a control unit. The detection unit is configured to detect a parameter of the RF power supply and a parameter of the load connected to the RF output end. According to the parameter of the RF power supply, the parameter of the load and a present value of a transformation ratio of a transformer, the control unit is at least configured to, calculate a target value of the transformation ratio of the transformer, and control the transformation-ratio adjustment unit to adjust the transformation ratio of the transformer to the target value of the transformation ratio, to compensate the reactance at the primary winding side of the RF circuit. The RF circuit includes the RF power supply, the RF output end, the transformer, the reactance compensation unit, and the transformation-ratio adjustment unit. The RF power supply is configured to provide RF power to the load. The RF output end is configured to be connected to the load. The transformer includes the primary winding and the secondary winding. The primary winding is connected between the RF power supply and the RF output end. The reactance compensation unit is connected in series with the secondary winding of the transformer, and is configured to selectively provide compensatory reactance. The transformation-ratio adjustment unit is configured to adjust the transformation ratio of the transformer. When reactance compensation is required for the RF circuit, the reactance compensation unit is configured to provide the compensatory reactance, and the transformation-ratio adjustment unit is configured to adjust the transformation ratio of the transformer, to compensate the reactance at the primary winding side of the RF circuit.

In a third aspect, a reactance compensation method is further provided. The reactance compensation method is performed by the aforementioned RF power-supply device, and is used to compensate the RF circuit of the RF power-supply device. The reactance compensation method includes as follows. Detecting, by a detection unit, the parameter of the RF power supply and the parameter of the load connected to the RF output end. Calculating, according to the parameter of the RF power supply, the parameter of the load, and the present value of the transformation ratio of the transformer, the target value of the transformation ratio of the transformer. Controlling the transformation-ratio adjustment unit to adjust the transformation ratio of the transformer to the target value of the transformation ratio, to compensate the reactance at the primary winding side of the RF circuit. The RF power-supply device includes the aforementioned RF circuit and further includes the detection unit and the control unit. The detection unit is configured to detect the parameter of the RF power supply and the parameter of the load connected to the RF output end. According to the parameter of the RF power supply, the parameter of the load and the present value of the transformation ratio of the transformer, the control unit is at least configured to, calculate the target value of the transformation ratio of the transformer, and control the transformation-ratio adjustment unit to adjust the transformation ratio of the transformer to the target value of the transformation ratio, to compensate the reactance at the primary winding side of the RF circuit.

### BRIEF DESCRIPTION OF THE DRAWINGS

In order to describe technical solutions in embodiments of the disclosure or the related art more clearly, the following will give an introduction to accompanying drawings required for describing embodiments or the related art.

FIG. 1 is a schematic circuit diagram of a radio frequency (RF) circuit in an embodiment of the disclosure.

FIG. 2 is a schematic circuit diagram of a first compensation-branch in another embodiment of the disclosure.

FIG. 3 is a schematic circuit diagram of a first compensation-branch in yet another embodiment of the disclosure.

FIG. 4 is a schematic circuit diagram of a second compensation-branch in another embodiment of the disclosure.

FIG. 5 is a schematic circuit diagram of a second compensation-branch in yet another embodiment of the disclosure.

FIG. 6 is a schematic circuit diagram of an RF circuit in another embodiment of the disclosure.

FIG. 7 is a schematic circuit diagram of an RF circuit in which a transformation-ratio adjustment unit is a rotation motor in an embodiment of the disclosure.

FIG. 8 is a schematic circuit diagram of an RF circuit further including a matching unit in an embodiment of the disclosure.

FIG. 9 is a schematic circuit diagram of an RF power-supply device in an embodiment of the disclosure.

FIG. 10 is a flowchart of a reactance compensation method in an embodiment of the disclosure.

FIG. 11 is a flowchart of a reactance compensation method in another embodiment of the disclosure.

### DESCRIPTION OF REFERENCE SIGNS OF THE ACCOMPANYING DRAWINGS

1—RF power—supply device; 10—RF circuit; 100—RF power supply; 200—RF output end; 210—first end; 220—second end; RL—load; 300—transformer; 310—primary winding; 320—secondary winding; n—transformation ratio; 400—reactance compensation unit; 411—first compensation—branch; L1—compensatory inductor; S2—first compensatory—switch; 412—second compensation—branch; C1—compensatory capacitor; S3—second compensatory—switch; 413 switch unit; S1—single-pole multi-throw switch; 414—third compensatory—switch; 500—transformation-ratio adjustment unit; 600—matching unit; 700—direct-output branch; S4—direct-output switch; GND—ground; 20—detection unit; L2—matching inductor; C2—matching capacitor; 30—control unit;

### DETAILED DESCRIPTION

Technical solutions in embodiments of the disclosure are clearly and completely described in the following with reference to accompanying drawings in embodiments of the disclosure. Apparently, the described embodiments are part rather than all of embodiments of the disclosure. All other embodiments obtained by those of ordinary skill in the art based on embodiments of the disclosure without creative effort are within the protection scope of the disclosure.

In the description embodiments of the disclosure, it should be noted that the orientation or positional relations indicated by terms such as “upper”, “inner”, “outer”, etc., are orientation or positional relationships based on the accompanying drawings, are only for facilitating the description of the disclosure and simplifying the description, rather than indicating or implying that the referred device or element must be in a particular orientation or constructed or operated in a particular orientation, and therefore cannot be construed as limiting the disclosure.

In the description of the disclosure, it should be noted that, unless specified or limited otherwise, the terms “couple”, “connect”, should be understood in a broad sense. For example, coupling may be a fixed coupling, or a detachable coupling, or an integrated coupling, may be a mechanical coupling, an electrical coupling, and may be a direct coupling, an indirect coupling through a medium. For those of ordinary skill in the art, the specific meaning of the above terms in the disclosure can be understood in specific cases.

It should be noted that, in the description of the embodiments of the disclosure, terms “first”, “second”, “third”, and the like are used for descriptive purposes only, and should not be understood as indicating or implying relative importance or implicitly indicating the number of technical features referred to herein. Therefore, features limited by “first”, “second”, “third”, and the like can explicitly or implicitly include one or more such feature. In the description of the disclosure, “multiple” or “a plurality of” refers to “at least two”, such as two, three, etc., unless otherwise explicitly specified.

In addition, the terms “include”, “have” and any variants thereof mean to cover the non-exclusive inclusion, for example, a process, method, system, product, or server that includes a list of steps or units is not necessarily limited to those expressly listed steps or units, but may include other steps or units not expressly listed or inherent to such a process, method, product, or device.

At present, with the popularization of various radio frequency (RF) applications, it becomes more and more important to perform impedance matching on an RF circuit, so as to obtain a maximum power value of a load.

However, a design of a present RF circuit has become more complex, and components have become more diversified. Whether a reactance of a load changes before the operation of the RF circuit or during the operation of the RF circuit, it is relatively difficult to perform reactance compensation on the RF circuit by adjusting the RF circuit. Therefore, how to perform the reactance compensation on the RF circuit conveniently has become an issue to be considered.

The disclosure provides an RF circuit, an RF power-supply device, and a reactance compensation method, which can perform reactance compensation on the RF circuit conveniently.

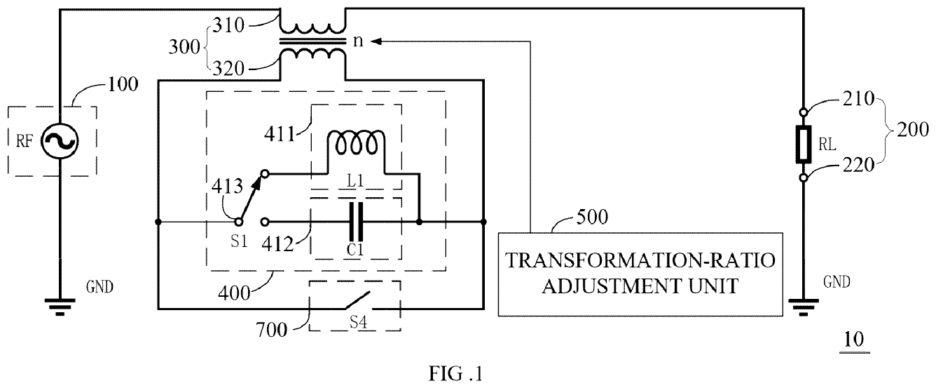

Reference can be made to FIG. 1, which is a schematic circuit diagram of an RF in an embodiment of the disclosure. As illustrated in FIG. 1, an RF circuit 10 is provided by the disclosure. The RF circuit 10 includes an RF power supply 100, an RF output end 200, a transformer 300, a reactance compensation unit 400, and a transformation-ratio adjustment unit 500. The RF power supply 100 is configured to provide RF power to a load RL. The RF output end 200 is configured to be connected to the load RL. The transformer 300 includes a primary winding 310 and a secondary winding 320. The primary winding 310 is connected between the RF power supply 100 and the RF output end 200. The reactance compensation unit 400 is connected in series with the secondary winding 320 of the transformer 300, and is configured to selectively provide a compensatory reactance. The transformation-ratio adjustment unit 500 is configured to adjust a transformation ratio n of the transformer 300. When the reactance compensation is required for the RF circuit 10, the reactance compensation unit 400 is configured to provide the compensatory reactance and the transformation-ratio adjustment unit 500 is configured to adjust the transformation ratio n of the transformer 300, to compensate a reactance at the primary winding 310 side of the RF circuit 10.

Therefore, the reactance compensation unit 400 and the secondary winding 320 of the transformer 300 are connected in series. The compensatory reactance can be provided selectively. The transformation ratio n of the transformer 300 is adjusted by the transformation-ratio adjustment unit 500. Thus the compensatory reactance can be provided by the reactance compensation unit 400 when the reactance compensation is required for the RF circuit 10. The transformation ratio n of the transformer 300 is adjusted by the transformation-ratio adjustment unit 500. Through the cooperation of the reactance compensation unit 400 and the ratio adjustment unit 500, the reactance at the primary winding 310 side of the RF circuit 10 is compensated conveniently and accurately. Thus, the impedance matching for the RF circuit 10 is achieved and the maximum power value of the load RL is obtained.

Specifically, the reactance at the primary winding 310 side of the RF circuit 10 is the sum of an internal reactance of the RF power supply 100, a reactance of the primary winding 310, and the reactance of the connected load RL. Whether the reactance of the load RL changes before the operation of the RF circuit 10 or during the operation of the RF circuit 10, the impedance matching is required for the RF circuit 10. When in an impedance matching state, the RF power supply 100 provides the RF power to the load RL, and the maximum power value of the load RL can be obtained. In other words, when an internal impedance of the RF power supply 100 of the RF circuit 10 matches with an impedance of the load RL connected to the RF output end 200, the value of the RF power provided by the RF power supply 100 is the power value of the load RL.

The transformer 300 can transfer reactive power. Primary power P1 is equal to secondary power P2. The primary power P1 and the secondary power P2 satisfy the following relational expressions: P1=n*U1²/Z1; and P2=U2²/Z2.

U1 is a primary voltage. Z1 is the reactance of the primary winding 310. U2 is a secondary voltage. Z2 is a secondary reactance. There are no any electrical consuming devices at the secondary winding 320 side of the RF circuit 10, so that the primary voltage U1 is equal to the secondary voltage U2. Therefore, the primary reactance Z1=n*Z2. When the secondary reactance Z2 is not zero, the reactance Z1 at the primary winding 310 can be changed by the adjustment of the transformation ratio n of the transformer 300 and/or by the adjustment of the secondary reactance Z2, so that the reactance at the primary winding 310 side of the RF circuit 10 can be changed. Thus, the reactance at the primary winding 310 side of the RF circuit 10 is compensated.

Furthermore, when the reactance compensation is required for the RF circuit 10, in the disclosure, it is unnecessary to adjust a circuit part at the primary winding 310 side of the RF circuit 10. The compensatory reactance is provided only for a circuit part at the secondary winding 320 side, and the transformation-ratio adjustment unit 500 adjusts the transformation ratio n of the transformer 300, so that the reactance at the primary winding 310 side of the RF circuit 10 can be compensated conveniently. Thus, the impedance matching for the RF circuit 10 is achieved and the maximum power value of the load RL is obtained.

In one or more embodiments, when the reactance compensation is required for the RF circuit 10, the reactance compensation unit 400 can provide the compensatory reactance first, and then the transformation-ratio adjustment unit 500 adjusts the transformation ratio n of the transformer 300, to compensate the reactance at the primary winding 310 side of the RF circuit 10. Thus, the reactance at the primary winding 310 side of the RF circuit 10 can be compensated by the compensatory reactance first, and then further compensated by adjusting the transformation ratio n of the transformer 300.

In one or more embodiments, when the reactance compensation is required for the RF circuit 10, the transformation-ratio adjustment unit 500 can also adjust the transformation ratio n of the transformer 300 first, and then the reactance compensation unit 400 provides the compensatory reactance. According to a reactance-compensation value required for the RF circuit 10 and a value of the compensatory reactance that the reactance compensation unit 400 can provide, the transformation ratio n of the transformer 300 is first adjusted to the target value of the transformation ratio, and then the compensatory reactance is provided. Therefore, the following disadvantages caused by a large difference between the present value of the transformation ratio of the transformer 300 and the target value of the transformation ratio can be avoided. An absolute value of the primary reactance at the primary winding 310 side is greater than the reactance-compensation value required for the RF circuit 10, or even the absolute value of the reactance Z1 at the primary winding 310 is greater than twice the reactance-compensation value required for the RF circuit 10, thereby causing the internal impedance of the RF power supply 100 of the RF circuit 10 and the impedance of the load RL connected to the RF output end 200 to be mismatched to a greater extent, and the power value of the load RL to be lower.

In one or more embodiments, when the reactance compensation is required for the RF circuit 10, the transformation-ratio adjustment unit 500 can also adjust the transformation ratio n of the transformer 300 first, then the reactance compensation unit 400 provides the compensatory reactance, and finally the transformation-ratio adjustment unit 500 further adjusts the transformation ratio n of the transformer 300. Therefore, when the reactance compensation is required for the RF circuit 10, the reactance at the primary winding 310 side of the RF circuit 10 can be compensated step by step to avoid excessive disturbance on the circuit part at the primary winding 310 side of the RF circuit 10.

In particular, in order to avoid counterproductive reactance compensation at the primary winding 310 side of the RF circuit 10, the reactance-compensation value can be reduced, or the transformation ratio n of the transformer 300 can be decreased in advance, or a compensation threshold can be set, so that when the reactance-compensation value required for the RF circuit 10 is less than the compensation threshold, the reactance compensation unit 400 does not provide the compensatory reactance. When a variation value of the reactance is greater than or equal to the compensation threshold, the reactance compensation unit 400 provides the compensatory reactance, and the transformation-ratio adjustment unit 500 adjusts the transformation ratio n of the transformer 300, to compensate the reactance at the primary winding 310 side of the RF circuit 10. The compensation threshold may be the absolute value of the difference between the compensatory reactance provided by the reactance compensation unit 400 and a minimum reactance Z1 at the primary winding 310.

The transformation ratio n of the transformer 300 is a ratio of the number of the turns of the primary winding 310 to the number of the turns of the secondary winding 320 of the transformer 300. The transformation ratio n can be adjusted by either adjusting the number of the turns of the primary winding 310 or adjusting the number of the turns of the secondary winding 320.

In one or more embodiments, an internal resistance value of the RF power supply 100 and a resistance value of the load RL can both be a standard resistance value of 50Ω. By performing the reactance compensation only on the RF circuit 10, the impedance matching between the internal impedance of the RF power supply 100 of the RF circuit 10 and the impedance of the load RL connected to the RF output end 200 can be realized, and it is more convenient for the RF circuit 10 to complete the impedance matching.

In one or more embodiments, the RF output end 200 includes a first end 210 and a second end 220. The first end 210 is connected to one end of the primary winding 310, and the second end is connected to ground (GND). One end of the RF power supply 100 is connected to the other end of the primary winding 310, and the other end of the RF power supply 100 is connected to GND.

As illustrated in FIG. 1, the reactance compensation unit 400 includes a first compensation-branch 411, a second compensation-branch 412, and a switch unit 413. The first compensation-branch 411 is inductive, and the second compensation-branch 412 is capacitive. The switch unit 413 is configured to connect, according to the type of the reactance exhibited at the primary winding 310 side, the first compensation-branch 411 or the second compensation-branch 412 in series with the secondary winding 320, to provide the compensatory reactance. The transformation-ratio adjustment unit 500 is configured to further adjust, according to the type of the reactance exhibited at the primary winding 310 side after compensated by the first compensation-branch 411 or the second compensation-branch 412, the transformation ratio n of the transformer 300, to further compensate the reactance at the primary winding 310 side of the RF circuit 10.

Therefore, the switch unit 413 can connect, according to the type of the reactance exhibited at the primary winding 310 side, the first compensation-branch 411 or the second compensation-branch 412 in series with the secondary winding 320, to provide the compensatory reactance. The transformation-ratio adjustment unit 500 can further adjust, according to the type of the reactance exhibited at the primary winding 310 side after compensated by the first compensation-branch 411 or the second compensation-branch 412, the transformation ratio n of the transformer 300, to further compensate the reactance at the primary winding 310 side of the RF circuit 10 conveniently. Thus, the impedance matching for the RF circuit 10 is achieved and the maximum power value of the load RL is obtained.

In one or more embodiments, the RF circuit 10 further includes a direct-output branch 700. The direct-output branch 700 is connected in parallel with the reactance compensation unit. The direct-output branch 700 includes a direct-output switch S4. The direct-output switch S4 is configured to connect the direct-output branch 700 in series with the secondary winding 320 and short-circuit the reactance compensation unit 400, when the reactance compensation is not required for the RF circuit 10. At this time, the reactance compensation unit 400 does not perform the reactance compensation.

Therefore, through the direct-output path, it is possible to avoid disabling the reactance compensation unit 400 and maintain the secondary winding 320 in the path when the reactance compensation is not required for the RF circuit 10, so that the impedance of the RF circuit 10 remains matched.

As illustrated in FIG. 1, the switch unit 413 is configured to connect the first compensation-branch 411 in series with the secondary winding 320 when the type of the reactance exhibited at the primary winding 310 side is capacitive, to provide the compensatory inductive reactance. The switch unit 413 is configured to connect the second compensation-branch 412 in series with the secondary winding 320 when the type of the reactance exhibited at the primary winding 310 side is inductive, to provide the compensatory capacitive reactance. The transformation-ratio adjustment unit 500 is further configured to further adjust, according to the type of the reactance exhibited at the primary winding 310 side after compensated by the first compensation-branch 411, the transformation ratio n of the transformer 300, to further compensate the reactance at the primary winding 310 side of the RF circuit 10.

Therefore, by providing the compensatory inductive reactance or the compensatory capacitive reactance according to the type of the reactance exhibited at the primary winding 310 side, and by further adjusting the transformation ratio n of the transformer 300 according to the type of the reactance exhibited at the primary winding 310 side after compensated by the first compensation-branch 411, it is possible to further compensate the reactance at the primary winding 310 side of the RF circuit 10.

In one or more embodiments, when the type of the reactance exhibited at the primary winding 310 side is capacitive, the switch unit 413 connects the first compensation-branch 411 in series with the secondary winding 320 to provide the compensatory capacitive reactance. When the type of the reactance exhibited at the primary winding 310 side after compensated by the first compensation-branch 411 is capacitive, the transformation ratio n of the transformer 300 is increased, and when type of the reactance exhibited at the primary winding 310 side after compensated by the first compensation-branch 411 is inducive, the transformation ratio n of the transformer 300 is decreased, so as to further compensate the reactance at the primary winding 310 side of the RF circuit 10. Similarly, when the type of the reactance exhibited at the primary winding 310 side is inductive, the switch unit 413 connects the second compensation-branch 412 in series with the secondary winding 320 to provide the compensatory inductive reactance. When the type of the reactance exhibited at the primary winding 310 side after compensated by the second compensation-branch 412 is inductive, the transformation ratio n of the transformer 300 is increased, and when the type of the reactance exhibited at the primary winding 310 side after compensated by the second compensation-branch 412 is capacitive, the transformation ratio n of the transformer 300 is decreased, so as to further compensate the reactance at the primary winding 310 side of the RF circuit 10.

As illustrated in FIG. 1, the switch unit 413 includes a single-pole multi-throw switch S1, which includes a common terminal and multiple traveler terminals. The common terminal is connected to one end of the secondary winding 320. The first compensation-branch 411 is connected between one of the multiple traveler terminals of the single-pole multi-throw switch S1 and the other end of the secondary winding 320, and the second compensation-branch 412 is connected between another traveler terminal of the multiple traveler terminals of the single-pole multi-throw switch S1 and the other end of the secondary winding 320. A throw terminal of the single-pole multiple-throw switch S1 can be selectively connected to one of the multiple traveler terminals, thereby connecting the first compensation-branch 411 or the second compensation-branch 412 in series with the secondary winding 320.

Therefore, according to the type of the reactance exhibited at the primary winding 310 side, the throw terminal of the single-pole multiple-throw switch S1 is selectively connected to one of the multiple traveler terminals, so as to connect the inductive first compensation-branch 411 or the capacitive second compensation-branch 412 in series with the secondary winding 320.

As illustrated in FIG. 1, the first compensation-branch 411 includes at least one compensatory inductor L1, and the second compensation-branch 412 includes at least one compensatory capacitor C1.

Therefore, the first compensation-branch 411 is inductive by means of the at least one compensatory inductive reactance L1, to provide the compensatory inductive reactance when the first compensation-branch 411 is connected in series with the secondary winding 320. The second compensation-branch 412 is capacitive by means of the at least one compensatory capacitor C1, to provide the compensatory capacitive reactance when the second compensation-branch 412 is connected in series with the secondary winding 320.

As illustrated in FIG. 1, the at least one compensatory inductor L1 is an adjustable inductor, and the at least one compensatory capacitor C1 is an adjustable capacitor. By adjusting the value of the at least one compensatory inductor L1 or the value of the at least one compensatory capacitor C1, a value of the compensatory inductive reactance or the compensatory capacitive reactance at the primary winding 310 side is conjugate to the reactance-compensation value required for the RF circuit 10.

Therefore, by providing the at least one compensatory inductor L1 as the adjustable inductor and by providing the at least one compensatory capacitor C1 as the adjustable capacitor, it is possible to adjust the value of the at least one compensatory inductor L1 or the value of the at least one compensatory capacitor C1 according to the type of the reactance exhibited at the primary winding 310 side, to perform auxiliary compensation on the type of the reactance exhibited at the primary winding 310 side of the RF circuit 10, thereby making the value of the compensatory inductive reactance or the value of the compensatory capacitive reactance at the primary winding 310 side is conjugate to the reactance-compensation value required for the RF circuit 10. Even without adjusting the transformation ratio n of the transformer 300, merely adjusting the value of the at least one compensatory inductor L1 or the value of the at least one compensatory capacitor C1 can compensate the reactance at the primary winding 310 side of the RF circuit 10. Thus, the impedance matching for the RF circuit 10 is achieved and the maximum power value of the load RL is obtained.

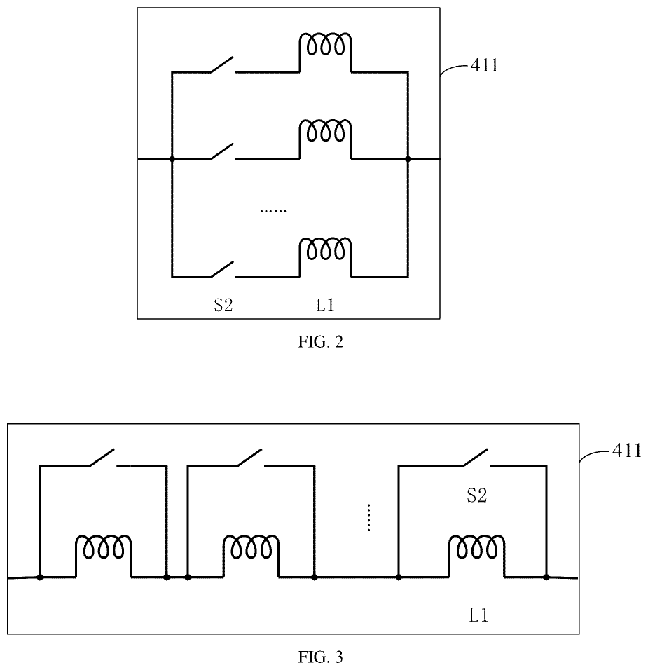

Reference can be made to FIG. 2 and FIG. 3. FIG. 2 is a schematic circuit diagram of a first compensation-branch in another embodiment of the disclosure. FIG. 3 is a schematic circuit diagram of a first compensation-branch in yet another embodiment of the disclosure. As illustrated in FIG. 2 and FIG. 3, the first compensation-branch 411 includes at least two compensatory inductors L1 connected in series or in parallel with each other, and at least two first compensatory switches S2. When the reactance exhibited at the primary winding 310 side is capacitive, the at least two first compensatory switches S2 are configured to connect the at least one compensatory inductor L1 in series with the secondary winding 320, to provide the compensatory inductive reactance, so that the value of the compensatory inductive reactance at the primary winding 310 side is conjugate to the reactance-compensation value required for the RF circuit 10.

Therefore, by providing the at least two compensatory inductors L1 connected in series or in parallel with each other, and the at least two first compensatory switches S2, it is possible to connect the at least one compensatory inductor L1 in series with the secondary winding 320 when the reactance exhibited at the primary winding 310 side is capacitive. The value of the compensatory inductive reactance provided at the primary winding 310 side is conjugate to the reactance-compensation value required for the RF circuit 10.

In one or more embodiments, each first compensatory switch S2 can connect one corresponding compensatory inductor L1 in series with the secondary winding 320, which facilitates controlling the connection and disconnection of each compensatory inductor L1.

In one or more embodiments, the compensatory inductive reactance provided by each compensatory inductor L1 may be the same or different. In other words, the value of each compensatory inductor L1 may be the same or different.

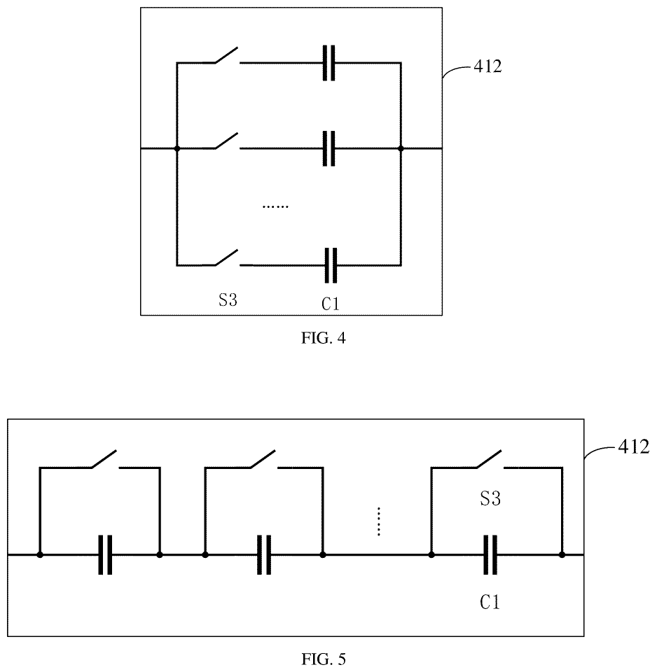

Reference can be made to FIG. 4 and FIG. 5. FIG. 4 is a schematic circuit diagram of a second compensation-branch in another embodiment of the disclosure. FIG. 5 is a schematic circuit diagram of a second compensation-branch in yet another embodiment of the disclosure. As illustrated in FIG. 4 and FIG. 5, the second compensation-branch 412 includes at least two compensatory capacitors C1 connected in series or in parallel with each other, and at least two second compensatory switches S3. When the reactance exhibited at the primary winding 310 side is inductive, the at least two second compensatory switches S3 are configured to connect the at least one compensatory capacitor C1 in series with the secondary winding 320, to provide the compensatory capacitive reactance, so that the value of compensatory capacitive reactance at the primary winding 310 side is conjugate to the reactance-compensation value required for the RF circuit 10.

Therefore, by providing the at least two compensatory capacitors C1 connected in series or in parallel with each other, and the at least two second compensatory switches S3, it is possible to connect the at least one compensatory capacitor C1 in series with the secondary winding 320 when the reactance exhibited at the primary winding 310 side is inductive. The value of the compensatory capacitive reactance provided at the primary winding 310 side is conjugate to the reactance-compensation value required for the RF circuit 10.

In one or more embodiments, each second compensatory switch S3 may connect one corresponding compensatory capacitor C1 in series with the secondary winding 320, which facilitates controlling the connection and disconnection of each compensatory capacitor C1.

In one or more embodiments, the compensatory capacitive reactance provided by each compensatory capacitor C1 may be the same or different. In other words, the value of each compensatory capacitor C1 may be the same or different.

In one or more embodiments, the first compensation-branch 411 may further include at least one auxiliary capacitor. The at least one auxiliary capacitor is connected in series or in parallel with the compensatory inductor L1. The second compensation-branch 412 may further include at least one auxiliary inductor. The at least one auxiliary inductor is connected in series or in parallel with the compensatory capacitor C1.

Therefore, by providing the at least one auxiliary capacitor, it is possible to perform auxiliary adjustment on the value of the compensatory inductive reactance provided by the first compensation-branch 411. By providing the at least one auxiliary inductor, it is possible to perform auxiliary adjustment on the value of the compensatory capacitive reactance provided by the second compensation-branch 412. Thus, the difficulty of accurately adjusting the value of the compensatory inductive reactance or the compensatory capacitive reactance provided by a single compensatory inductor L1 and compensatory capacitor C1 can be avoided.

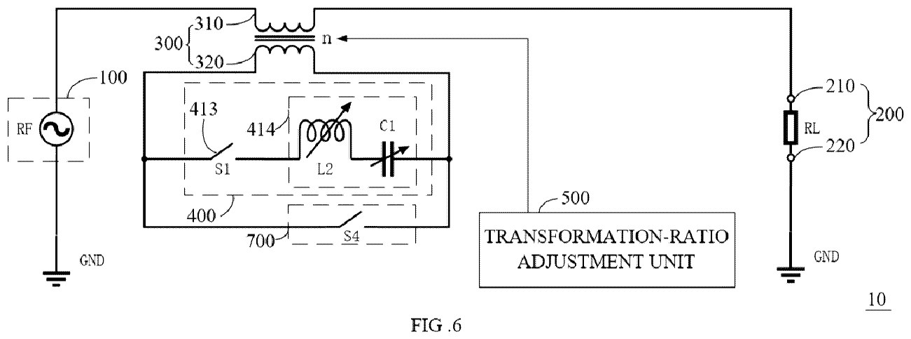

Reference can be made to FIG. 6, which is a schematic circuit diagram of an RF circuit in another embodiment of the disclosure. As illustrated in FIG. 6, the reactance compensation unit 400 includes a third compensation-branch 414 and the switch unit 413. The third compensation-branch 414 is inductive or capacitive. The switch unit 413 is configured to connect, according to the type of the reactance exhibited at the primary winding 310 side, the third compensation-branch 414 in series with the secondary winding 320, the third compensation-branch 414 in series with the secondary winding 320, to provide the compensatory inductive reactance or the compensatory capacitive reactance. The transformation-ratio adjustment unit 500 is configured to further adjust the transformation ratio n of the transformer 300 according to the type of the reactance exhibited at the primary winding 310 side after compensated by the third compensation-branch 414, to further compensate the reactance at the primary winding 310 side of the RF circuit 10.

Therefore, the switch unit 413 can connect, according to the type of the reactance exhibited at the primary winding 310 side, the third compensation-branch 414 in series with the secondary winding 320, to provide the compensatory inductive reactance or the compensatory capacitive reactance. The transformation-ratio adjustment unit 500 can further adjust, according to the type of the reactance exhibited at the primary winding 310 side after compensated by the third compensation-branch 414, to further compensate the reactance at the primary winding 310 side of the RF circuit 10 conveniently. Thus, the impedance matching for the RF circuit 10 is achieved and the maximum power value of the load RL is obtained.

The at least one compensatory inductor L1 is an adjustable inductor, and the at least one compensatory capacitor C1 is an adjustable capacitor. By adjusting the value of the at least one compensatory inductor L1 or the at least one compensatory capacitor C1, the value of the compensatory inductive reactance or the value of compensatory capacitive reactance at the primary winding 310 side is conjugate to the reactance compensation value required by the RF circuit 10.

Therefore, compared with the reactance compensation unit 400 of the RF circuit 10 illustrated in the embodiment of FIG. 1, the first compensation-branch 411 that is inductive and the second compensation-branch 412 that is capacitive are not required for the reactance compensation unit 400 of the RF circuit 10 of another embodiment illustrated in FIG. 6, only one compensation-branch, namely the third compensation-branch 414 in FIG. 6 is required, so that the compensatory inductive reactance or the compensatory capacitive reactance can be provided. In addition, the adjustable inductor and the adjustable capacitor of the third compensation-branch 414 can also accurately adjust a value of provided compensation reactance.

In one or more embodiments, the case in which the reactance compensation is required for the RF circuit 10 includes the case in which the power of the load RL changes. When the power of the load RL changes, the reactance compensation unit 400 is configured to provide the compensatory reactance. The transformation-ratio adjustment 500 unit is further configured to adjust, in an adjustment direction and by an adjustment amplitude, the transformation ratio n of the transformer 300, to compensate the reactance at the primary winding 310 side of the RF circuit 10. The adjustment direction is the increase direction or the decrease direction of the transformation ratio n of the transformer 300, and the adjustment amplitude is the variation value of the transformation ratio n in the adjustment direction.

Therefore, when the power of the load RL changes, it is determined that the reactance compensation is required for the RF circuit 10. The reactance compensation unit 400 provides the compensatory reactance, and the transformation-ratio adjustment unit 500 adjusts the ratio n of the transformer 300 in the adjustment direction and by the adjustment amplitude, to accurately compensate the reactance at the primary wingding 310 side of the RF circuit 10.

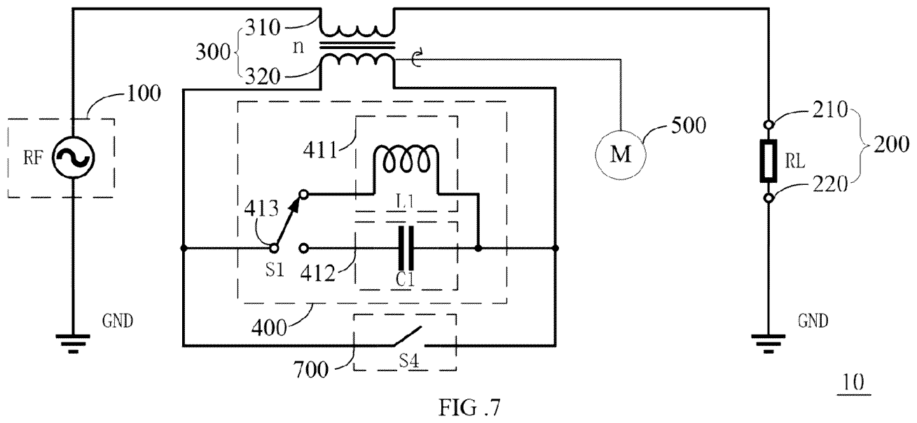

Reference can be made to FIG. 7, which is a schematic circuit diagram of an RF circuit in which a transformation-ratio adjustment unit is a rotation motor in an embodiment of the disclosure. As illustrated in FIG. 7, the transformation-ratio adjustment unit 500 may be a rotation motor. The adjustment direction is a rotation direction of the rotation motor, and the adjustment amplitude is the number of rotation turns or a specific rotation angle of the rotation motor.

Specifically, the transformer 300 further includes an iron core. The primary winding 310 may include a primary winding bobbin for winding wires of the primary winding 310, and the primary winding bobbin is rotatably sleeved on the iron core. The secondary winding 320 may include a secondary winding bobbin for winding wires of the secondary winding 320, and the secondary winding bobbin is rotatably sleeved on the iron core. The rotation shaft of the rotation motor is fixedly connected to the primary winding bobbin or the secondary winding bobbin. Taking the rotation shaft of the rotation motor illustrated in FIG. 7 being fixedly connected to the secondary winding bobbin as an example, when the rotation motor rotates, the rotation shaft of the rotation motor drives the secondary winding bobbin to rotate. As a result, the number of turns of wires of the secondary winding wound on the secondary winding bobbin increases or decreases under the action of the rotation of the secondary winding bobbin, thereby adjusting the transformation ratio n of the transformer 300 to increase or decrease.

The rotation direction includes a first direction and a second direction. The first direction is opposite to the second direction. When the rotation motor rotates in the first direction, the adjustment direction may be the increase direction of the transformation ratio n of the transformer 300. Correspondingly, when the rotation motor rotates in the second direction, the adjustment direction is the decrease direction of the transformation ratio n of the transformer 300. When the motor rotates in the first direction, the adjustment direction may also be the decrease direction of the transformation ratio n of the transformer 300. Correspondingly, when the motor rotates in the second direction, the adjustment direction is the increase direction of the transformation ratio n of the transformer 300.

When the power of the load RL changes continuously within the preset time period, the transformation-ratio adjustment unit 500 is further configured to adjust, at the adjustment speed, the transformation ratio n of the transformer 300, to compensate the continuously changing reactance at the primary winding side 310 within the preset time period. The adjustment speed is the variation value of the transformation ratio n per unit time. Therefore, when the power of the load RL changes continuously within the preset time period, the transformation-ratio unit 500 adjusts the transformation ratio n of the transformer 300 at the adjustment speed, thereby compensating the reactance at the primary winding 310 side of the RF circuit 10 in real time.

In one or more embodiments, the adjustment speed is a rotation speed of the rotation motor.

In one or more embodiments, when the load RL does not change continuously within the preset time period, the transformation-ratio adjustment unit 500 can adjust the transformation ratio n of the transformer 300 only in the adjustment direction and by the adjustment amplitude, to compensate the reactance at the primary winding 310 side of the RF circuit 10. When the load RL changes continuously within the preset time period, the transformation-ratio adjustment unit 500 can simultaneously adjust the transformation ratio n of the transformer 300, in the adjustment direction, by the adjustment amplitude, and at the adjustment speed, to compensate the continuously changing reactance at the primary winding 310 side within the preset time period.

In one or more embodiments, when the load RL changes slowly within the preset time period, the transformation-ratio adjustment unit 500 can also adjust the transformation ratio n of the transformer 300 only in the adjustment direction and by adjustment amplitude, to compensate the reactance at the primary winding 310 side of the RF circuit 10. That is to say, a change-rate threshold can be set. When a change rate of the load RL within the preset time period is less than the change-rate threshold, the transformation-ratio adjustment unit 500 adjusts the transformation ratio n of the transformer 300 in the adjustment direction and by adjustment amplitude. When the change rate of the load RL within the preset time period is greater than or equal to the change-rate threshold, the transformation-ratio adjustment unit 500 adjusts the transformation ratio n of the transformer 300 in the adjustment direction, by the adjustment amplitude, and at the adjustment speed.

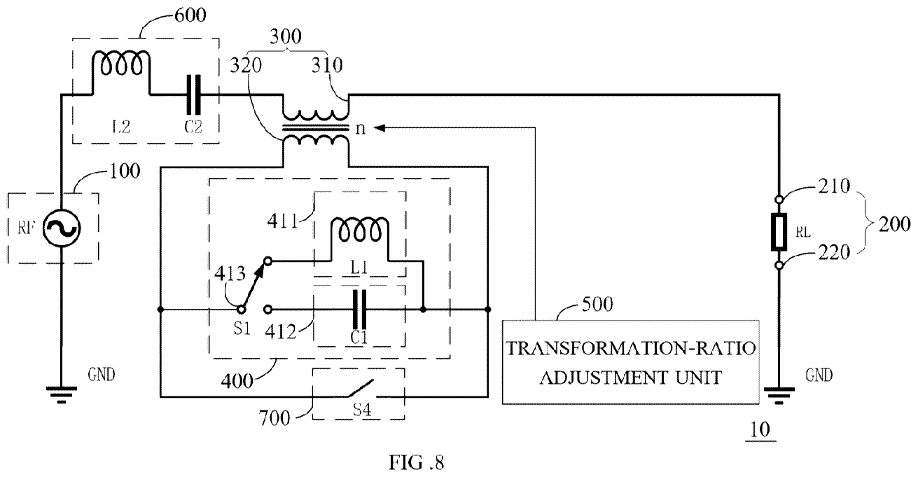

Reference can be made to FIG. 8, which is a schematic circuit diagram of an RF circuit further including a matching unit in an embodiment of the disclosure. As illustrated in FIG. 8, the RF circuit 10 further includes a matching unit 600. The matching unit 600 is located in the output path of the RF power from the RF power supply 100 to the load RL, and is configured to cooperate with the reactance compensation unit 400 to match the reactance at the primary winding 310 side of RF the circuit 10.

Therefore, the reactance compensation unit 400 cooperates with the matching unit 600 to match the reactance at the primary winding 310 side of RF the circuit 10.

In one or more embodiments, the matching unit 600 may be connected between the RF power supply 100 and the RF output end 200, or may be located inside the RF power supply 100.

In one or more embodiments, when the load RL is a purely resistive load, and the internal resistance value of the RF power supply 100 and the resistance value of the load RL are both standard resistance values of 50Ω, it is more convenient for the RF circuit 10 to perform the impedance matching before the operation of the RF circuit 10. The matching unit 600 can cooperate with the reactance compensation unit 400 to perform the reactance matching only on the internal reactance of the RF power supply 100, thereby achieving the impedance matching between the internal impedance of the RF power supply 100 and the impedance of the load RL.

In one or more embodiments, when the load RL is an inductive load or a capacitive load, and the internal resistance value of the RF power supply 100 and the resistance value of the load RL are both standard resistance values of 50Ω, the matching unit 600 can be further configured to cooperate with the reactance compensation unit 400, to perform the reactance matching on the reactance of the load RL, thereby achieving the impedance matching between the internal impedance of the RF power supply 100 and the impedance of the load RL.

In one or more embodiments, when the internal resistance value of the RF power supply 100 is not consistent with the resistance value of the load RL, the matching unit 600 can be further configured to perform the impedance matching between the internal resistance of the RF power supply 100 and the resistance of the load RL, thereby achieving the impedance matching between the internal impedance of the RF power supply 100 and the impedance of the load RL.

In one or more embodiments, the matching unit 600 may include at least one matching inductor L2 and at least one matching capacitor C2. The at least one matching inductor L2 is connected in series or in parallel with the at least one matching capacitor C2. The matching unit 600 may further include other resistive components such as matching resistors. The present disclosure is not limited thereto, as long as the matching unit 600 can at least achieve the reactance matching for the internal reactance of the RF power supply 100.

The RF circuit 10 is provided in the disclosure. By means of the aforementioned structure, it is unnecessary to adjust the circuit part at the primary winding 310 side of the RF circuit 10. The compensatory reactance is only provided at the circuit part at the secondary winding 320 side, and the transformation-ratio adjustment unit 500 adjusts the transformation ratio n of the transformer 300, so that the reactance at the primary winding 310 side of the RF circuit 10 can be compensated conveniently and in real time. Thus, the impedance matching for the RF circuit 10 is achieved and the maximum power value of the load RL is obtained.

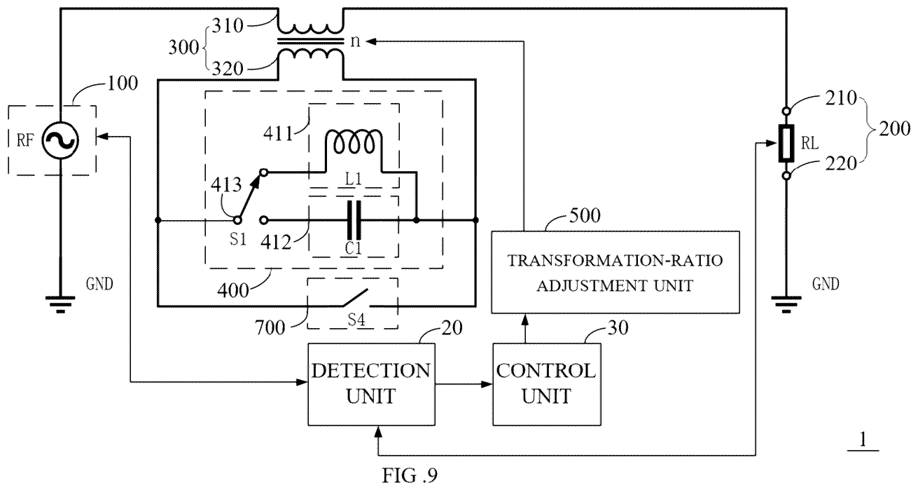

Reference can be made to FIG. 9, is a schematic circuit diagram of an RF power-supply device in an embodiment of the disclosure. As illustrated in FIG. 9, an RF power-supply device 1 is further provided by the disclosure. The RF power-supply device 1 includes the abovementioned RF circuit 10, and further includes a detection unit 20 and a control unit 30. The detection unit 20 is configured to detect a parameter of the RF power supply 100 and a parameter of the load RL connected to the RF output end 200. According to the parameter of the RF power supply 100, the parameter of the load RL, and a present value of the transformation ratio n of the transformer 300, the control unit 30 is at least configured to calculate a target value of the transformation ratio of the transformer 300, and control the transformation-ratio adjustment unit 500 to adjust the transformation ratio n of the transformer 300 to the target value of the transformation ratio, to compensate the reactance at the primary winding 310 side of the RF circuit 10.

As illustrated in FIG. 9, the RF circuit 10 includes the RF power supply 100, the RF output end 200, the transformer 300, the reactance compensation unit 400, and the transformation-ratio adjustment unit 500. The RF power supply 100 is configured to provide the RF power to the load RL. The RF output end 200 is configured to be connected to the load RL. The transformer 300 includes the primary winding 310 and the secondary winding 320. The primary winding 310 is connected between the RF power supply 100 and the RF output end 200. The reactance compensation unit 400 is connected in series with the secondary winding 320 of the transformer 300, and is configured to selectively provide the compensatory reactance. The transformation-ratio adjustment unit 500 is configured to adjust the transformation ratio n of the transformer 300. When the reactance compensation is required for the RF circuit 10, the reactance compensation unit 400 is configured to provide the compensatory reactance and the transformation-ratio adjustment unit 500 is configured to adjust the transformation ratio n of the transformer 300, to compensate the reactance at the primary winding 310 side of the RF circuit 10.

The more specific structure of the RF circuit 10 can be referred to the relevant content of the RF circuit 10 in any of the aforementioned embodiments, and will not be repeated here.

Therefore, the detection unit 20 detects the parameter of the RF power supply 100 and the parameter of the load RL connected to the RF output end 200. According to the parameter of the RF power supply 100, the parameter of the load RL, and the present value of the transformation ratio n of the transformer 300, the control unit 30 at least calculates the target value of the transformation ratio of the transformer 300, and controls the transformation-ratio adjustment unit 500 to adjust the transformation ratio n of the transformer 300 to the target value of the transformation ratio, to compensate the reactance at the primary winding 310 side of the RF circuit 10.

In one or more embodiments, the detection unit 20 may include a voltage detection unit, a current detection unit, and the like. The voltage detection unit may be a voltmeter, or other voltage detection devices such as a voltage sensor, or a voltage detection circuit composed of resistors, capacitors, diodes, and other components. The current detection unit may be an ammeter, or other current detection devices such as a Hall sensor, or a current detection circuit composed of resistors, capacitors, diodes, and other components.

In one or more embodiments, the control unit 30 is further configured to determine an adjustment parameter of the transformation-ratio adjustment unit 500, according to the parameter of the RF power supply 100, the parameter of the load RL, the present value of the transformation ratio of the transformer 300, and the target value of the transformation ratio of the transformer 300. The parameter of the RF power supply 100 includes the value of the RF power provided by the RF power supply, the parameter of the load RL at least includes the power value of the load RL, and the adjustment parameter at least includes an adjustment direction and an adjustment amplitude of the transformation-ratio adjustment unit 500.

Therefore, the adjustment parameter of the transformation-ratio adjustment unit 500 is determined by the control unit 30, so that the reactance at the primary winding 310 side of the RF circuit 10 is accurately compensated.

In one or more embodiments, the detection unit 20 is configured to detect values of RF voltage and RF current of the RF power supply 100, and voltage values and current values across the load RL. The control unit 30 is configured to obtain, according to the values of the RF voltage and RF current of the RF power supply 100, and the voltage values and current values across the load RL, the value of the RF power provided by the RF power supply 100 and the power value of the load RL. The control unit 30 is further configured to calculate the target value of the transformation ratio of the transformer 300 according to the present value of the transformation ratio of the transformer 300, and control the transformation-ratio adjustment unit 500 to adjust the transformation ratio n of the transformer 300 to the target value of the transformation ratio, so as to compensate the reactance at the primary winding 310 side of the RF circuit 10.

In one or more embodiments, the adjustment parameter further includes the adjustment speed of the transformation-ratio adjustment unit 500. Thus, the reactance at the primary winding 310 side of the RF circuit 10 is compensated in real time.

When the transformation-ratio adjustment unit 500 is the rotation motor, the adjustment direction is the rotation direction of the rotating motor, the adjustment amplitude is the number of rotation turns or the specific rotation angle of the rotation motor, and the adjustment speed is the rotation speed of the rotating motor.

In one or more embodiments, the control unit 30 may be a general-purpose processor such as a central processing unit (CPU), or may be a digital signal processor (DSP), an application-specific integrated circuit (ASIC), a field-programmable gate array (FPGA), or other programmable logic components, discrete gate logic components, transistor logic components, and the like. The control unit 30 may also be a microprocessor such as a micro control unit 100.

The RF circuit 10 and the RF power-supply device 1 are provided in the present disclosure. The parameter of the RF power supply 100 and the parameter of the load RL connected to the RF output end 200 are detected by the detection unit 20. The target value of the transformation ratio of the transformer 300 is calculated by the control unit 30 at least according to the parameter of the RF power supply 100, the parameter of the load RL, and the present value of the transformation ratio n of the transformer 300. The transformation-ratio adjustment unit 500 is controlled to adjust the transformation ratio n of the transformer 300 to the target value of the transformation ratio. Therefore, by means of the aforementioned structure, the reactance at the primary winding 310 side of the RF circuit 10 can be compensated conveniently and in real time. Thus, the impedance matching for the RF circuit 10 is achieved and the maximum power value of the load RL is obtained.

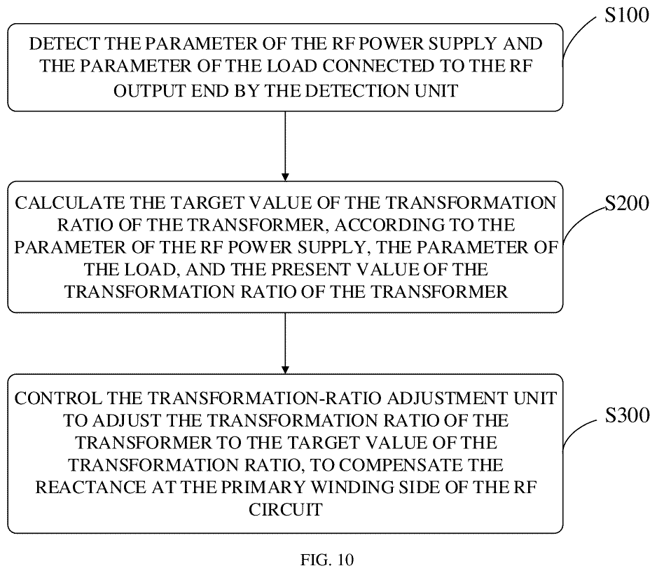

Reference can be made to FIG. 10, which is a flowchart of a reactance compensation method in an embodiment of the disclosure. As illustrated in FIG. 10, the reactance compensation method is further provided by the disclosure and is performed by the RF power-supply device 1. The reactance compensation method is used to compensate the RF circuit 10 of the RF power-supply device 1, and the reactance compensation method comprises as follows.

At S100, the parameter of the RF power supply and the parameter of the load connected to the RF output end is detected by the detection unit.

At S200, the target value of the transformation ratio of the transformer is calculated, according to the parameter of the RF power supply, the parameter of the load, and the present value of the transformation ratio of the transformer.

At S300, the transformation-ratio adjustment unit is controlled to adjust the transformation ratio of the transformer to the target value of the transformation ratio, to compensate the reactance at the primary winding side of the RF circuit.

As illustrated in FIG. 9, the RF power-supply device 1 includes the above-mentioned RF circuit 10, and further includes the detection unit 20 and the control unit 30. The detection unit 20 is configured to detect the parameter of the RF power supply 100 and the parameter of the load RL connected to the RF output end 200. According to the parameter of the RF power supply 100, the parameter of the load RL, and the present value of the transformation ratio n of the transformer 300, the control unit 30 is at least configured to calculate the target value of the transformation ratio of the transformer 300, and control the transformation-ratio adjustment unit 500 to adjust the transformation ratio n of the transformer 300 to the target value of the transformation ratio, to compensate the reactance at the primary winding 310 side of the RF circuit 10.

The more specific structure of the RF power-supply device 1 can be referred to the relevant content of the RF power-supply device 1 in any of the aforementioned embodiments, and will not be repeated here.

Therefore, the parameter of the RF power supply 100 and the parameter of the load RL connected to the RF output end 200 are detected. According to the parameter of the RF power supply 100, the parameter of the load RL, and the present value of the transformation ratio n of the transformer 300, the target value of the transformation ratio of the transformer 300 is calculated. The transformation-ratio adjustment unit 500 is controlled to adjust the transformation ratio n of the transformer 300 to the target value of the transformation ratio. Thus, the reactance at the primary winding 310 side of the RF circuit 10 is compensated.

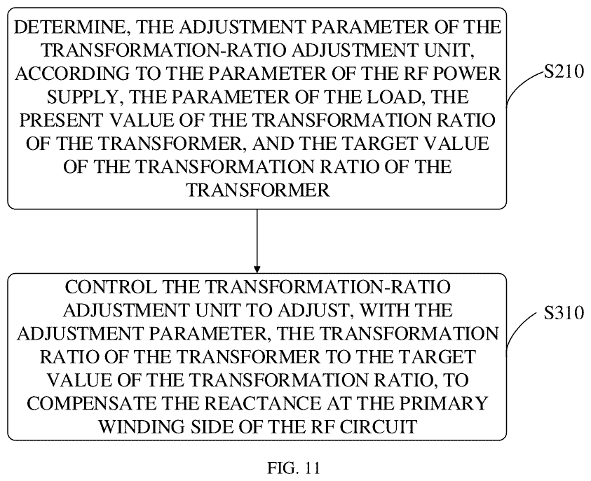

Reference can be made to FIG. 11, which is a flowchart of a reactance compensation method in another embodiment of the disclosure. As illustrated in FIG. 10 and FIG. 11, after S200, that is, after calculating, according to the parameter of the RF power supply, the parameter of the load, and the present value of the transformation ratio of the transformer, the target value of the transformation ratio of the transformer, the reactance compensation method further includes as follows.

At S210, the adjustment parameter of the transformation-ratio adjustment unit is determined, according to the parameter of the RF power supply, the parameter of the load, the present value of transformation ratio of the transformer, and the target value of the transformation ratio of the transformer.

The parameter of the RF power supply 100 includes the value of the RF power provided by the RF power supply, the parameter of the load RL at least includes the power value of the load RL, and the adjustment parameter at least includes the adjustment direction and the adjustment amplitude of the transformation-ratio adjustment unit 500.

Therefore, the adjustment parameter of the transformation-ratio adjustment unit 500 is determined, so that the reactance at the primary winding 310 side of the RF circuit 10 is accurately compensated.

As illustrated in FIG. 10 and FIG. 11, at S300, controlling the transformation-ratio adjustment unit to adjust the transformation ratio of the transformer to the target value of the transformation ratio, to compensate the reactance at the primary winding side of the RF circuit, includes as follows.

At S310, the transformation-ratio adjustment unit is controlled to adjust, with the adjustment parameter, the transformation ratio of the transformer to the target value of the transformation ratio, to compensate the reactance at the primary winding side of the RF circuit.

In one or more embodiments, the adjustment parameter further includes the adjustment speed of the transformation-ratio adjustment unit 500. Thus, the reactance at the primary winding 310 side of the RF circuit 10 is compensated in real time.

In one or more embodiments, the control unit 30 of the RF power-supply device 1 performs the abovementioned reactance compensation method, to compensate the RF circuit 10 of the RF power-supply device 1.

The RF circuit 10, the RF power-supply device 1 and the reactance compensation method are provided in the disclosure. By means of the aforementioned structure and method, it is unnecessary to adjust the circuit part of the primary winding 310 side of the RF circuit 10. The compensatory reactance is only provided at the circuit part of the secondary winding 320 side, and the transformation-ratio adjustment unit 500 adjusts the transformation ratio n of the transformer 300, so that the reactance at the primary winding 310 side of the RF circuit 10 can be compensated conveniently and in real time. Thus, the impedance matching for the RF circuit 10 is performed and the maximum power value of the load RL is obtained.

The above descriptions are only the specific implementations of the disclosure, but the protection scope of the disclosure is not limited to the above. Any skilled in the technical field can easily think of changes or replacements within the technical scope of the disclosure, and the changes or replacements should be covered in the protection scope of the disclosure. The embodiments of the disclosure and features in the embodiments may be mutually combined without conflicts. Therefore, the protection scope of the disclosure shall be subject to the protection scope of the claims.

What is claimed is:

1. A radio frequency (RF) circuit, comprising:
an RF power supply configured to provide RF power to a load;
an RF output end configured to be connected to the load;
a transformer comprising a primary winding and a secondary winding, wherein the primary winding is connected between the RF power supply and the RF output end;
a reactance compensation unit, wherein the reactance compensation unit is connected in series with the secondary winding of the transformer, and the secondary winding is configured to selectively provide compensatory reactance; and
a transformation-ratio adjustment unit configured to adjust a transformation ratio of the transformer;
wherein when reactance compensation is required for the RF circuit, the reactance compensation unit is configured to provide the compensatory reactance and the transformation-ratio adjustment unit is configured to adjust the transformation ratio of the transformer, to compensate a reactance at a primary winding side of the RF circuit.

2. The RF circuit of claim 1, wherein the reactance compensation unit comprises a first compensation-branch, a second compensation-branch and a switch unit, the first compensation-branch is inductive, and the second compensation-branch is capacitive;
wherein the switch unit is configured to connect, according to a type of a reactance exhibited at the primary winding side, the first compensation-branch or the second compensation-branch in series with the secondary winding, to provide the compensatory reactance; and the transformation-ratio adjustment unit is configured to further adjust, according to a type of the reactance exhibited at the primary winding side after compensated by the first compensation-branch or the second compensation-branch, the transformation ratio of the transformer, to further compensate the reactance at the primary winding side of the RF circuit.

3. The RF circuit of claim 2, wherein the switch unit is configured to connect the first compensation-branch in series with the secondary winding when the type of the reactance exhibited at the primary winding side is capacitive, to provide a compensatory inductive reactance; and the switch unit is configured to connect the second compensation-branch in series with the secondary winding when the type of the reactance exhibited at the primary winding side is inductive, to provide a compensatory capacitive reactance; and
the transformation-ratio adjustment unit is further configured to further adjust, according to the type of the reactance exhibited at the primary winding side after compensated by the first compensation-branch, the transformation ratio of the transformer, to further compensate the reactance at the primary winding side of the RF circuit.

4. The RF circuit of claim 1, wherein a case in which the reactance compensation is required for the RF circuit comprises a case in which power of the load changes, and when the power of the load changes, the reactance compensation unit is configured to provide the compensatory reactance; and the transformation-ratio adjustment unit is further configured to adjust, in an adjustment direction and by an adjustment amplitude, the transformation ratio of the transformer, to compensate the reactance at the primary winding side of the RF circuit; wherein the adjustment direction is an increase direction or a decrease direction of the transformation ratio of the transformer, and the adjustment amplitude is a variation value of the transformation ratio in the adjustment direction.

5. The RF circuit of claim 4, wherein when the power of the load changes continuously within a preset time period, the transformation-ratio adjustment unit is further configured to adjust, at an adjustment speed, the transformation ratio of the transformer, to compensate the continuously changing reactance at the primary winding side within the preset time period; wherein the adjustment speed is a variation value of the transformation ratio per unit time.

6. The RF circuit of claim 1, wherein the RF circuit further comprises a matching unit, the matching unit is located in an output path of the RF power from the RF power supply to the load, and is configured to cooperate with the reactance compensation unit to match the reactance at the primary winding side of the RF circuit.

7. The RF circuit of claim 1, wherein the RF circuit further comprises a direct-output branch, the direct-output branch is connected in parallel with the reactance compensation unit, the direct-output branch comprises a direct-output switch, and the direct-output switch is configured to connect the direct-output branch in series with the secondary winding and short-circuit the reactance compensation unit when the reactance compensation is not required for the RF circuit.

8. A radio frequency (RF) power-supply device, wherein the RF power-supply device comprises an RF circuit, the RF circuit comprises an RF power supply, an RF output end, a transformer, a reactance compensation unit, and a transformation-ratio adjustment unit, the RF power supply is configured to provide RF power to a load, the RF output end is configured to be connected to the load, the transformer comprises a primary winding and a secondary winding, the primary winding is connected between the RF power supply and the RF output end, the reactance compensation unit is connected in series with the secondary winding of the transformer, the secondary winding is configured to selectively provide compensatory reactance, and the transformation-ratio adjustment unit is configured to adjust a transformation ratio of the transformer; wherein when reactance compensation is required for the RF circuit, the reactance compensation unit is configured to provide the compensatory reactance and the transformation-ratio adjustment unit is configured to adjust the transformation ratio of the transformer, to compensate a reactance at a primary winding side of the RF circuit; and the RF power-supply device further comprises:
a detection unit, wherein the detection unit is configured to detect a parameter of the RF power supply and a parameter of the load connected to the RF output end; and
a control unit, wherein according to the parameter of the RF power supply, the parameter of the load, and a present value of a transformation ratio of a transformer, the control unit is at least configured to calculate a target value of the transformation ratio of the transformer, and control the transformation-ratio adjustment unit to adjust the transformation ratio of the transformer to the target value of the transformation ratio, to compensate the reactance at the primary winding side of the RF circuit.

9. The RF power-supply device of claim 8, wherein the control unit is further configured to determine an adjustment parameter of the transformation-ratio adjustment unit, according to the parameter of the RF power supply, the parameter of the load, the present value of the transformation ratio of the transformer, and the target value of the transformation ratio of the transformer; wherein the parameter of the RF power supply comprises a value of the RF power provided by the RF power supply, the parameter of the load at least comprises a power value of the load, and the adjustment parameter at least comprises an adjustment direction and an adjustment amplitude of the transformation-ratio adjustment unit.

10. The RF power-supply device of claim 8, wherein the reactance compensation unit comprises a first compensation-branch, a second compensation-branch and a switch unit, the first compensation-branch is inductive, and the second compensation-branch is capacitive;
wherein the switch unit is configured to connect, according to a type of a reactance exhibited at the primary winding side, the first compensation-branch or the second compensation-branch in series with the secondary winding, to provide the compensatory reactance; and the transformation-ratio adjustment unit is configured to further adjust, according to a type of the reactance exhibited at the primary winding side after compensated by the first compensation-branch or the second compensation-branch, the transformation ratio of the transformer, to further compensate the reactance at the primary winding side of the RF circuit.

11. The RF power-supply device of claim 10, wherein the switch unit is configured to connect the first compensation-branch in series with the secondary winding when the type of the reactance exhibited at the primary winding side is capacitive, to provide a compensatory inductive reactance; and the switch unit is configured to connect the second compensation-branch in series with the secondary winding when the type of the reactance exhibited at the primary winding side is inductive, to provide a compensatory capacitive reactance; and
the transformation-ratio adjustment unit is further configured to further adjust, according to the type of the reactance exhibited at the primary winding side after compensated by the first compensation-branch, the transformation ratio of the transformer, to further compensate the reactance at the primary winding side of the RF circuit.

12. The RF power-supply device of claim 8, wherein a case in which the reactance compensation is required for the RF circuit comprises a case in which power of the load changes, and when the power of the load changes, the reactance compensation unit is configured to provide the compensatory reactance; and the transformation-ratio adjustment unit is further configured to adjust, in an adjustment direction and by an adjustment amplitude, the transformation ratio of the transformer, to compensate the reactance at the primary winding side of the RF circuit; wherein the adjustment direction is an increase direction or a decrease direction of the transformation ratio of the transformer, and the adjustment amplitude is a variation value of the transformation ratio in the adjustment direction.

13. The RF power-supply device of claim 12, wherein when the power of the load changes continuously within a preset time period, the transformation-ratio adjustment unit is further configured to adjust, at an adjustment speed, the transformation ratio of the transformer, to compensate the continuously changing reactance at the primary winding side within the preset time period; wherein the adjustment speed is a variation value of the transformation ratio per unit time.

14. The RF power-supply device of claim 8, wherein the RF circuit further comprises a matching unit, the matching unit is located in an output path of the RF power from the RF power supply to the load, and is configured to cooperate with the reactance compensation unit to match the reactance at the primary winding side of the RF circuit.

15. The RF power-supply device of claim 8, wherein the RF circuit further comprises a direct-output branch, the direct-output branch is connected in parallel with the reactance compensation unit, the direct-output branch comprises a direct-output switch, and the direct-output switch is configured to connect the direct-output branch in series with the secondary winding and short-circuit the reactance compensation unit when the reactance compensation is not required for the RF circuit.

16. A reactance compensation method, performed by the radio frequency (RF) power-supply device of claim 8, wherein the reactance compensation method is used to compensate the RF circuit of the RF power-supply device, and the reactance compensation method comprises:
detecting, by a detection unit, the parameter of the RF power supply and the parameter of the load connected to the RF output end;
calculating, according to the parameter of the RF power supply, the parameter of the load, and the present value of the transformation ratio of the transformer, the target value of the transformation ratio of the transformer; and
controlling the transformation-ratio adjustment unit to adjust the transformation ratio of the transformer to the target value of the transformation ratio, to compensate the reactance at the primary winding side of the RF circuit.

17. The reactance compensation method of claim 16, wherein after calculating, according to the parameter of the RF power supply, the parameter of the load, and the present value of the transformation ratio of the transformer, the target value of the transformation ratio of the transformer, the reactance compensation method further comprises:
determining, according to the parameter of the RF power supply, the parameter of the load, the present value of transformation ratio of the transformer, and the target value of the transformation ratio of the transformer, an adjustment parameter of the transformation-ratio adjustment unit;
wherein the parameter of the RF power supply comprises a value of the RF power provided by the RF power supply, the parameter of the load at least comprises a power value of the load, and the adjustment parameter at least comprises an adjustment direction and an adjustment amplitude of the transformation-ratio adjustment unit.
